(19) United States
(12) Patent Application Publication
(10) Pub. No.: US 2004/0210810 A1
(43) Pub. Date: Oct. 21, 2004

(54) Test method and circuit for testing inter-device connections of field programmable gate arrays

(76) Inventor: Fang-Bin Liu, Taoyuan (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/760,998

(22) Filed: Jan. 20, 2004

(30) Foreign Application Priority Data
Jan. 24, 2003 (TW) 92101571

(51) Int. Cl. G01R 31/28

(52) U.S. Cl. 714/733

(57) ABSTRACT

A method and circuit for performing an on-board test of connections between field programmable gate arrays (FPGAs) By the method, circuit structures can be adjusted according to the width of a bus, simplifying connection testing between on-board FPGAs. Moreover, bus quality and speed can be functionally tested by the method. Because FPGAs are reprogrammable, the present invention can be employed without additional cost.

### BACKGROUND OF THE INVENTION

1. Field of the Invention

The present invention relates to a test of bus connections between components, and in particular to a method and circuit for performing an on-board test of connections between field programmable gate arrays (FPGAs) of the bus can be tested functionally by the method.

2. Description of the Related Art

FPGA chips have commonly been packaged by the Ball Grid Array (BGA) method to meet size requirements, especially regarding pins. With BGA the dimensions have become so small that it is difficult to test pin functionality.

Currently, pin functionality is tested by X-ray and an pattern estimation program or operator successively. The bus quality test is performed by probing to determine whether two points are active. The connection test, however, is applicable only to circuits and therefore does not yield sufficient data.

### SUMMARY OF THE INVENTION

Accordingly, an object of the present invention is to provide a method and circuit for performing an on-board test of connections between FPGAs. The method allows circuit structures to be adjusted according to the bus width, thus simplifying connection testing between on-board FPGAs. Moreover, bus quality and speed can be functionally tested by the described method.

Using the test circuit comprising a linear feedback shift register (LFSR), it is easy to acquire connection status and the bus quality information.

The method comprises the steps of disposing a first connection circuit on a first programmable array circuit, such as FPGA, according to a preset LFSR polynomial, disposing a second connection circuit on a second programmable array circuit, wherein pins of the second connection circuit are connected to the corresponding pins of the first connection circuit in one-pin-to-one-pin and parallel layout. In one example, one of the two connection circuits has an XOR gate and the other circuit has a shift register. In another example, one circuit has both an XOR gate and a shift register. A pattern is input to the shift register to be processed by the shift register and a specific pattern is produced from an output pin of the shift register is corresponding to the connection status and relevant information about the first and the second connection circuits. The shift register comprises a plurality of D-type flip-flops connected in serial.

The test circuit comprises a first connection circuit connected to a first FPGA and a second connection circuit having a shift register and connected between the first connection circuit and a second FPGA, wherein the first and the second connection circuits are disposed according to a preset linear feedback shift register (LFSR) polynomial, wherein a test pattern is input to and processed by the shift register, and then a specific pattern is produced from an output pin of the shift register, and wherein the specific pattern is corresponding to the connection status of the first and the second connection circuits. The shift register comprises a plurality of D-type flip-flops connected in serial. In this case the first connection circuit has an XOR gate and the second connection circuit has a shift register, and in another case the second connection circuit has both an XOR gate and a shift register.

A detailed description is given in the following embodiment with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1a is a schematic diagram showing the polynomial circuit structure of an LFSR circuit with XOR gates outside the shift register.

FIG. 1b is a schematic diagram showing the polynomial circuit structure of an LFSR circuit with XOR gates inside the shift register.

FIG. 2a is a schematic diagram showing the polynomial circuit structure of an LFSR circuit with XOR gates outside the shift register of the present invention.

FIG. 2b is a schematic diagram showing the polynomial circuit structure of an LFSR circuit with gates inside the shift register of the present invention.

FIG. 3a is a schematic diagram showing the test circuit integrated with an LFSR circuit with XOR gates outside the shift register of the present invention.

FIG. 3b is a schematic diagram showing an embodiment according to the FIG. 3a.

FIG. 4a is a schematic diagram showing the test circuit integrated with an LFSR circuit with XOR gates inside the shift register of the present invention.

FIG. 4b is a schematic diagram showing an embodiment according to the FIG. 4a.

FIG. 5 is a flowchart showing the test process of the present invention.

### DETAILED DESCRIPTION OF THE INVENTION

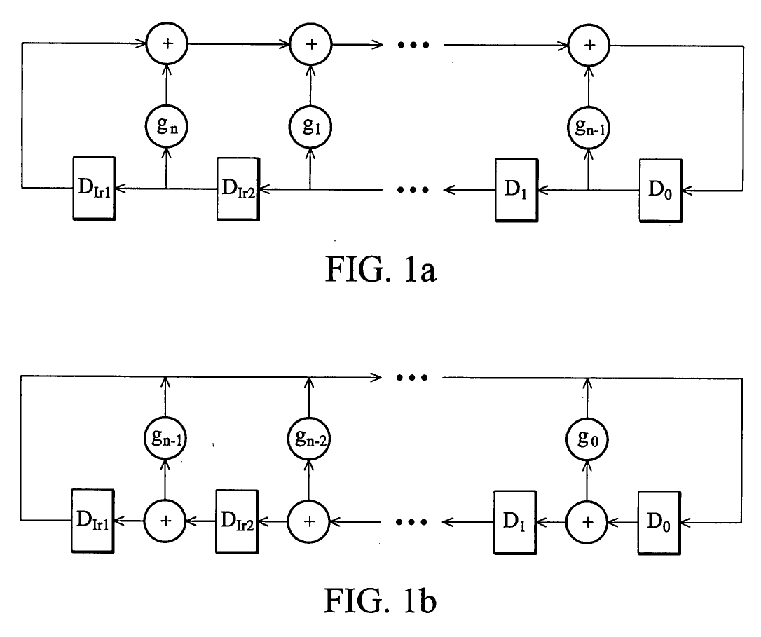

There are two types of LFSR polynomial circuit structures. An LFSR with XOR gates outside the shift register as shown in FIG. 1a and an LFSR circuit with XOR gates inside the shift register as shown in FIG. 1b.

Basically, a unit of an LFSR comprises a plurality of D-type flip-flops and a plurality of XOR gates. The D-type flip-flops are connected in serial and constitute a shift register. The disposition of the XOR gates determines the characteristic polynomial of the LFSR. The general formula of the structures in FIGS. 1a and 1b can be represented as follow:

g(x)=gₙxⁿ+gₙ₋₁xⁿ⁻¹+Λ+g₀x⁰.

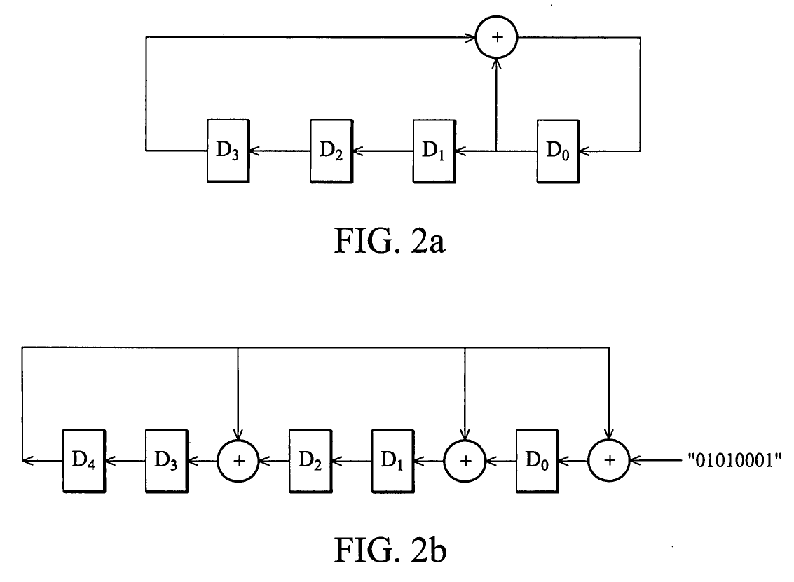

In practice, the formula can be used to design any desired LFSR polynomial circuit. For example, FIG. 2a shows an LFSR circuit with a characteristic polynomial of g(x)=x⁴+x³+1, and the initial value is set to 1. FIG. 2b shows an LFSR circuit with a characteristic polynomial of g(x)=x⁵+x³+X+1, and the initial value is set to 0.

The disposition of the XOR gates determines representation of the characteristic polynomial of the LFSR for any possible form of the characteristic polynomial. A test pattern, for example, “01010001” in FIG. 2b (namely, the pattern is x+x³+x⁷), is input to and processed by the shift register. In other words, the test pattern is divided by the characteristic polynomial. If the output pattern is not equal to the predicted pattern, the remainder, an error is happened. By examining the disposition of the XOR gates relating to the output pattern, connection status and relevant information can be acquired. By the recursive feature of the LFSR, the LFSR operates in a fixed sequence, so the output pattern can be acquired and represented as follows:

$$G ( x ) = \frac{{\sum }_{i = 1}^{n} {g}_{i} {x}^{i} ( {a}_{- i} {x}^{- i} + Λ + {a}_{- 1} {x}^{- 1} )}{g ( x )} ,$$

wherein G(x) is the output pattern, a₋ᵢ is the initial state of the flip-flop Dᵢ, and g(x) is the characteristic polynomial. When the parameter gᵢ is equal to 1, the corresponding XOR gate exists in the connection, otherwise the corresponding XOR gate does not exist in the connection.

Thus, the functional test of the bus and the connection can be accomplished by examining whether a particular pattern is correct or not. Another example with a characteristic polynomial of g(x)=1+x+x²+x³ is introduced hereinafter to further explain the test circuit and method of the present invention.

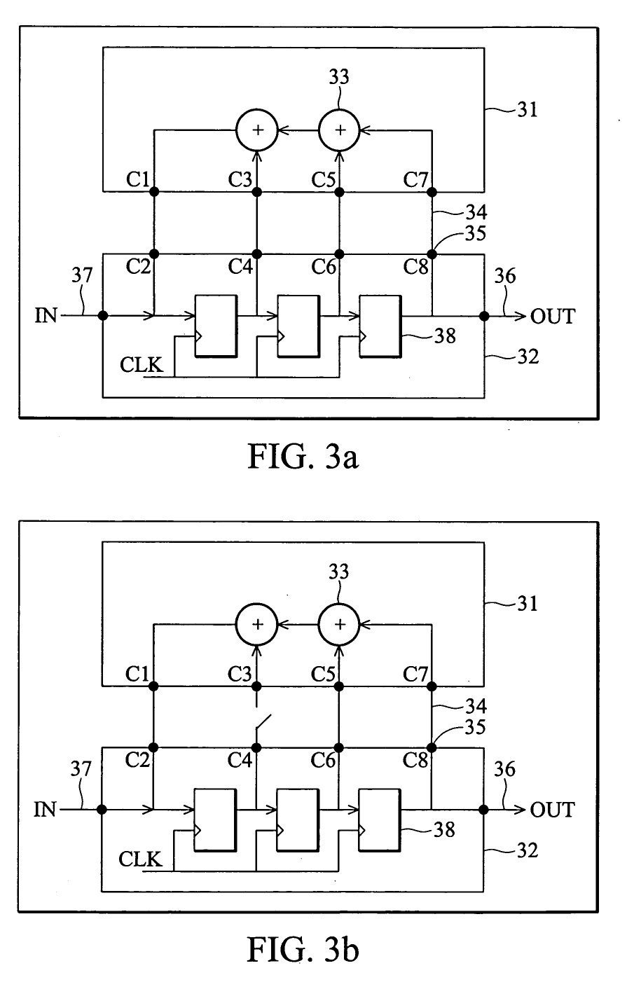

FIG. 3a is a schematic diagram of a test circuit of the present invention. As shown in FIG. 3a, the test circuit comprises two FPGAs 31 and 32, two XOR gates 33, a plurality of buses 34, a plurality of pins 35 of FPGAs, an output pin 36, an input pin 37, and a shift register 38. The shift register comprises a plurality of D-type flip-flops connected in serial.

As shown in FIG. 3a, a LFRS polynomial circuit is established by the connections, namely the buses 34, between two FPGAs 31 and 32 to perform the test method. Put simply, using the division feature of the polynomial, after establishing the circuit, a fixed pattern IN is input to the shift register 38 via the input pin 37, and then an output pattern OUT from the output pin 36 is examined. If any of the bus connection lines are connected incorrectly or disconnected, the polynomial formed by the circuit is incomplete and has a corresponding missing term. After inputting a pattern “1111” via the input pin, the pattern OUT is detected as erroneous. Therefore, g(x) is able to be derived by reversing the formula G(x). If the characteristic polynomial is g(x)=1+x²+x³ as shown in FIG. 3b and both the polynomial circuit and the input pattern are known, the erroneous connection line relating to the first-order item x is easily detected. Moreover, using polynomial division feature, when 0 or 1 is randomly transmitted on the buses 34 and the clock speed varies, the bus speed can be decided according to the corresponding output situation. In addition, the appearance of cross talk can be detected upon the occurrence of an incompatible condition gap.

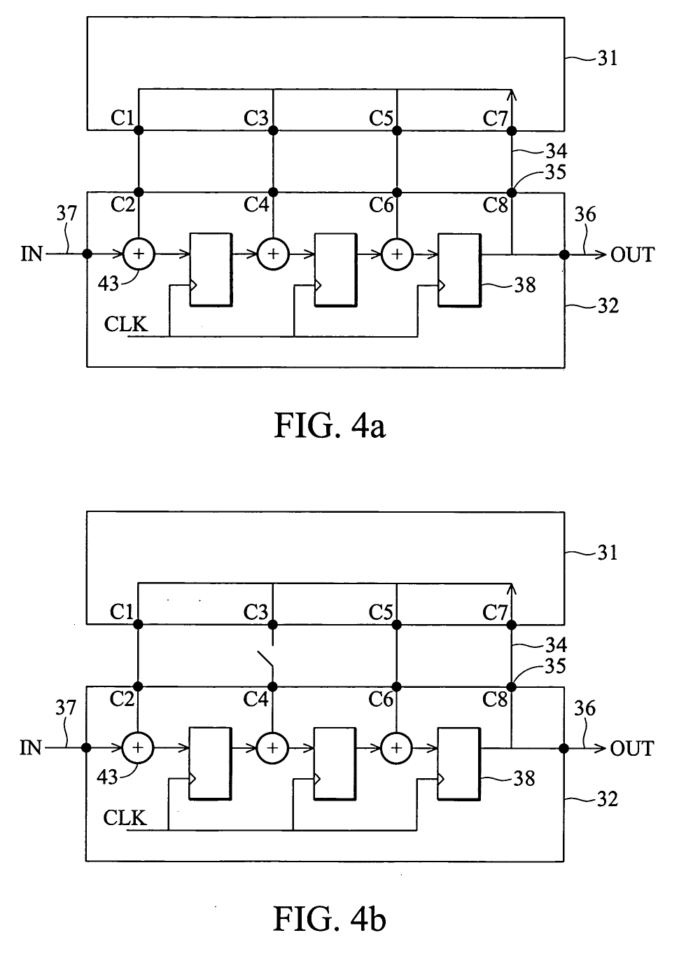

FIG. 4a is a schematic diagram of another test circuit of the present invention. As shown in FIG. 4a, the test circuit comprises two FPGAs 31 and 32, three XOR gates 43, a plurality of buses 34, a plurality of pins 35 of FPGAs, an output pin 36, an input pin 37, and a shift register 38. The shift register comprises a plurality of D-type flip-flops connected in serial.

Different from the circuit structure used in FIG. 3a, FIG. 4a uses an LFSR circuit with the XOR gates inside the shift register to perform the test method. The LFRS polynomial circuit is established by the connections, namely the buses 34, between two FPGAs 31 and 32. Put simply, there is one XOR gate disposed before each D-type flip-flop, and an output end of the XOR gate is connected to an input end of the D-type flip-flop. Therefore, three XOR gates 43 are required to establish the LFSR polynomial circuit. Using the polynomial division feature, after establishing the circuit, a fixed pattern IN is input to the shift register 38 via the input pin 37, and then an output pattern-OUT from the output pin 36 is examined. If any of the bus connection lines are incorrectly connected or disconnected, the polynomial formed by the circuit is not complete and has a corresponding missing term. After inputting a pattern “1111” via the input pin, the pattern OUT is detected as erroneous. Therefore, g(x) can be derived by reversing the formula G(x). If the output characteristic polynomial is g(x)=1+x+x³ as shown in FIG. 4b and both the polynomial circuit and the input pattern are known, the erroneous connection line relating to the second—order item x² is easily determined. Moreover, using the polynomial division feature, when 0 or 1 is randomly transmitted on the buses 34 and the clock speed varies, the bus speed can be decided according to the corresponding output. In addition, the appearance of cross talk can be detected upon occurrence of an incompatible condition gap.

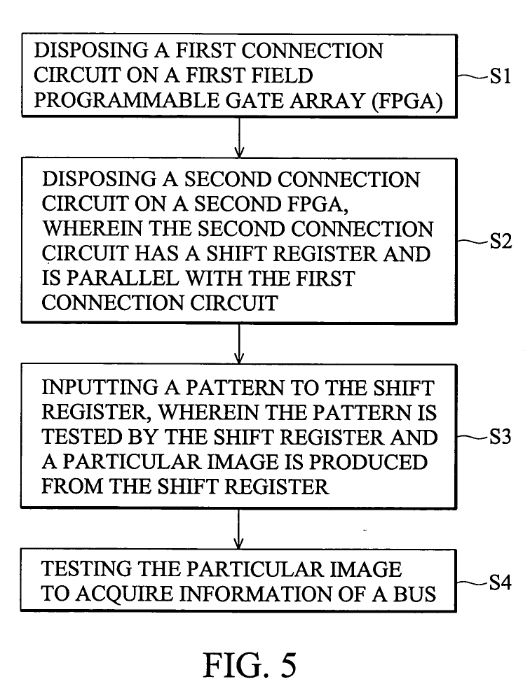

FIG. 5 is a flowchart showing the test process of the present invention. The method comprises the steps of (S1) disposing a first connection circuit on a first FPGA according to a preset LFSR polynomial, (S2) disposing a second connection circuit on a second FPGA, wherein pins of the second connection circuit are connected to the corresponding pins of the first connection circuit in one-pin-to-one-pin and parallel style and wherein in one case one of the two connection circuits has an XOR gate and the other circuit has a shift register, and in another case one circuit has both the XOR gate and the shift register, (S3) inputting a pattern to the shift register, wherein the pattern is tested by the shift register and wherein a particular pattern is produced from an output pin of the shift register, and (S4) testing the particular pattern to acquire a connection status and relevant information of the first and the second connection circuits. The shift register comprises a plurality of D-type flip-flops connected in serial.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for performing an on-board test of connections between two programmable array circuits, comprising the steps of:
disposing a first connection circuit on a first programmable array circuit according to a preset linear feedback shift register (LFSR) polynomial;
disposing a second connection circuit on a second programmable array circuit according to the preset LFSR polynomial, wherein the second connection circuit has a shift register and wherein pins of the second connection circuit are connected to the corresponding pins of the first connection circuit;
inputting a test pattern to the shift register, wherein the test pattern is processed by the shift register circuit and wherein a particular pattern is produced from an output pin of the shift register; and
examining the particular pattern to acquire a connection status of the first and the second connection circuits.

2. The method as claimed in claim 1, wherein the shift register comprises a plurality of D-type flip-flops connected in serial.

3. The method as claimed in claim 1, wherein a plurality of XOR gates are disposed in the first connection circuit when an LFSR circuit with the XOR gates outside the shift register is used to achieve the preset LFSR polynomial.

4. The method as claimed in claim 1, wherein a plurality of XOR gates are disposed in the second connection circuit when an LFSR circuit with the XOR gates inside the shift register is used to achieve the preset LFSR polynomial.

5. The method as claimed in claim 1, wherein the test pattern and the particular pattern are related in the form of a polynomial.

6. The method as claimed in claim 1, wherein the status includes bus speed and an appearance of cross talk.

7. The method as claimed in claim 1, wherein the programmable arrays circuits are FPGAs.

8. A circuit for performing an on-board test of connections between two programmable arrays circuits, comprising:
a first connection circuit connected with a first programmable arrays circuit; and
a second connection circuit having a shift register and connected between the first connection circuit and a second programmable arrays circuit,
wherein the first and the second connection circuits are disposed according to a preset linear feedback shift register (LFSR) polynomial, wherein a test pattern is input to and processed by the shift register, and then a particular pattern is produced from an output pin of the shift register, and wherein the particular pattern is examined to acquire a connection status of the first and the second connection circuits.

9. The method as claimed in claim 8, wherein the shift register comprises a plurality of D-type flip-flops connected in serial.

10. The method as claimed in claim 8, wherein the first connection circuit has a plurality of XOR gates when an LFSR circuit with the XOR gates outside the shift register is used to achieve the preset LFSR polynomial.

11. The method as claimed in claim 8, wherein the second connection circuit has a plurality of XOR gates when an LFSR circuit with the XOR gates inside the shift register is used to achieve the preset LFSR polynomial.

12. The method as claimed in claim 8, wherein the test pattern and the particular pattern are related in the form of a polynomial.

13. The method as claimed in claim 8, wherein the programmable arrays circuits are FPGAs.
